(19) United States
(12) Patent Application Publication
(10) Pub. No.: US 2011/0272548 A1
(43) Pub. Date: Nov. 10, 2011

(54) VIDEO BEZEL SEAT ATTACHMENT

(75) Inventors: Leon Rudkowski, Winston-Salem, NC (US); Alexander Pozzi, Winston-Salem, NC (US)

(73) Assignee: BE AEROSPACE, INC., Wellington, FL (US)

(21) Appl. No.: 12/776,638

(22) Filed: May 10, 2010

(51) Int. Cl. H05K 7/14; B23P 11/00; F16B 2/20

(52) U.S. Cl. 248/231.81; 29/428

(57) ABSTRACT

A bezel assembly includes a bezel including an outer surface in which a recess is formed for receiving a video monitor, an inner side contoured to engage a seat back frame opposite the outer surface, a retaining lip extending outwardly from the inner side, and an internal rib connected to the inner side. At least one spring clip attaches the retaining lip to the seat back frame, and at least one spring-loaded connector attaches the internal rib to the seat back frame.

### TECHNICAL FIELD OF THE INVENTION

This invention relates generally to a bezel for a video monitor, and more particularly to a bezel for mounting a video monitor onto a seat back.

### BACKGROUND OF THE INVENTION

A typical airline passenger cabin is equipped with one or more video monitors along the ceiling of the cabin above an aisle between columns of seats. These monitors are viewed by many passengers at once, and so each passenger has little or no choice in selecting content to be viewed. Passengers nonetheless have a variety of tastes. There are typically both adults and children present, and so the selection of age-appropriate content, for example, is not well served by a single monitor being viewed by a cabin full of passengers.

Video monitors are becoming increasingly available in large and small sizes, and are becoming increasingly affordable. Thus, in the interest of engaging and entertaining all passengers, it would be desirable to provide a dedicated video monitor for particular viewing by each passenger. Personal video monitors for mounting within automobiles have straps and the like for attaching the monitors to seat backs and visors and such. However, in an airline environment, temporary straps and the like are undesirable because they have cluttered appearances and they invite handling and tampering by curious passengers such as children.

Therefore an arrangement for mounting a video monitor for personal viewing in an aircraft passenger cabin is needed.

### BRIEF SUMMARY OF THE INVENTION

It is an object of the present invention to provide a bezel assembly for mounting a video monitor onto a back of a passenger seat. In one embodiment the bezel assembly includes a bezel having an outer surface in which a recess is formed for receiving a video monitor, an inner side contoured to engage a seat back frame opposite the outer surface, a retaining lip extending outwardly from the inner side, and an internal rib connected to the inner side. This embodiment of the bezel assembly also includes at least one spring clip for attaching the retaining lip to the seat back frame; and at least one spring-loaded connector for attaching the internal rib to the seat back frame.

In at least one example, the spring clip includes a mounting plate, a retaining shoulder connected perpendicularly to the mounting plate, and a turned edge connected to the retaining shoulder and extending away from the mounting plate to guide the retaining lip of the bezel.

In at least one example, the bezel has a peripheral wall from which the retaining lip extends outwardly, a hooked flange extending outwardly from the peripheral wall, and a channel formed between the retaining lip and the hooked flange.

In at least one example, the spring-loaded connector includes a cylindrical shaft and a wide key, and the bezel assembly further includes a bracket for attaching the internal rib to the seat back frame in cooperation with the spring-loaded connector. An aperture formed through the bracket has a central hole for receiving the shaft and radial slots for passage of the wide key.

In at least one example, the bracket includes a mounting plate and a retaining shelf in which the aperture is formed. The retaining shelf is connected perpendicularly to the mounting plate.

In at least one example, the bezel has a peripheral wall in which an access hole is formed for permitting access to the spring-loaded connector.

It is another object of the present invention to provide a method of attaching a video monitor bezel onto a back of a passenger seat. The method includes providing a seat back frame, and providing a bezel having an outer surface in which a recess is formed for receiving a video monitor, an inner side contoured to engage the seat back frame opposite the outer surface, a retaining lip extending outwardly from the inner side, and an internal rib connected to the inner side. The method further comprises providing a spring clip connected to the seat back frame, and providing a connector having a cylindrical shaft and a wide key. The retaining lip is attached to the seat back frame by engaging the retaining lip with the spring clip, and the internal rib is attached to the seat back frame by a quarter turn of the connector.

### BRIEF DESCRIPTION OF THE DRAWINGS

The subject matter that is regarded as the invention may be best understood by reference to the following description taken in conjunction with the accompanying drawing figures in which:

FIG. 1 is a perspective view of a video monitor bezel mounted on a seat back according to one embodiment of the present invention;

FIG. 2 shows the bezel of FIG. 1 with broken view areas in which attachment components along the top of the bezel are shown;

FIG. 3 is a cut-away view showing a retaining lip of the bezel engaged by a spring clip;

FIG. 4 is cross-sectional perspective view of the retaining lip engaged by the spring clip;

FIG. 5 is an exploded perspective view of the components illustrated in FIG. 4;

FIG. 6 is an exploded perspective view in which attachment components along the bottom of the bezel are shown;

FIG. 7 is a cut-away view of the attachment components of FIG. 6 being engaged to mount the bezel on the seat back; and

FIGS. 8 and 9 are cross-sectional views of the components of FIG. 6.

### DETAILED DESCRIPTION OF THE INVENTION

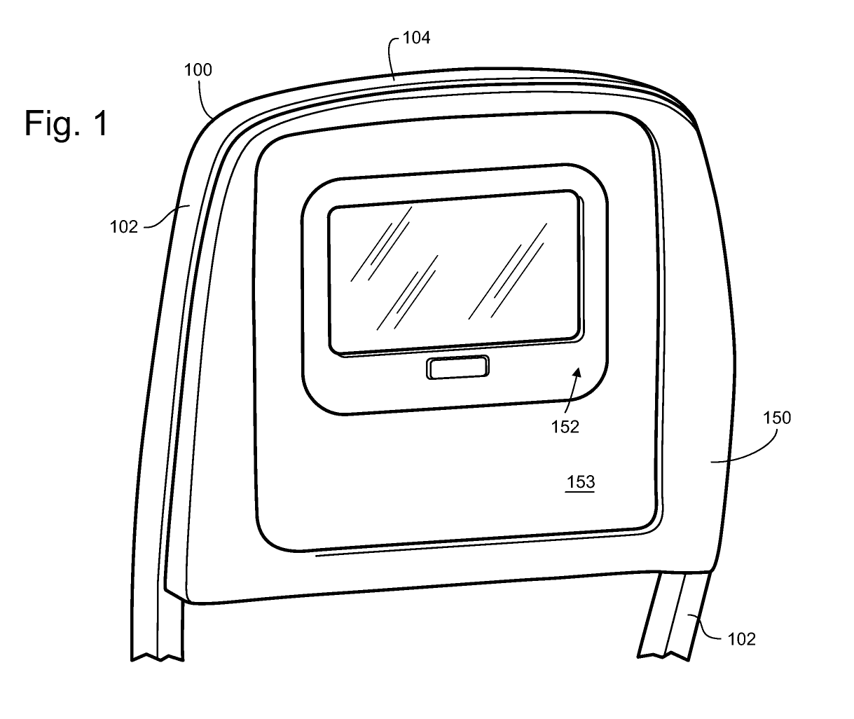

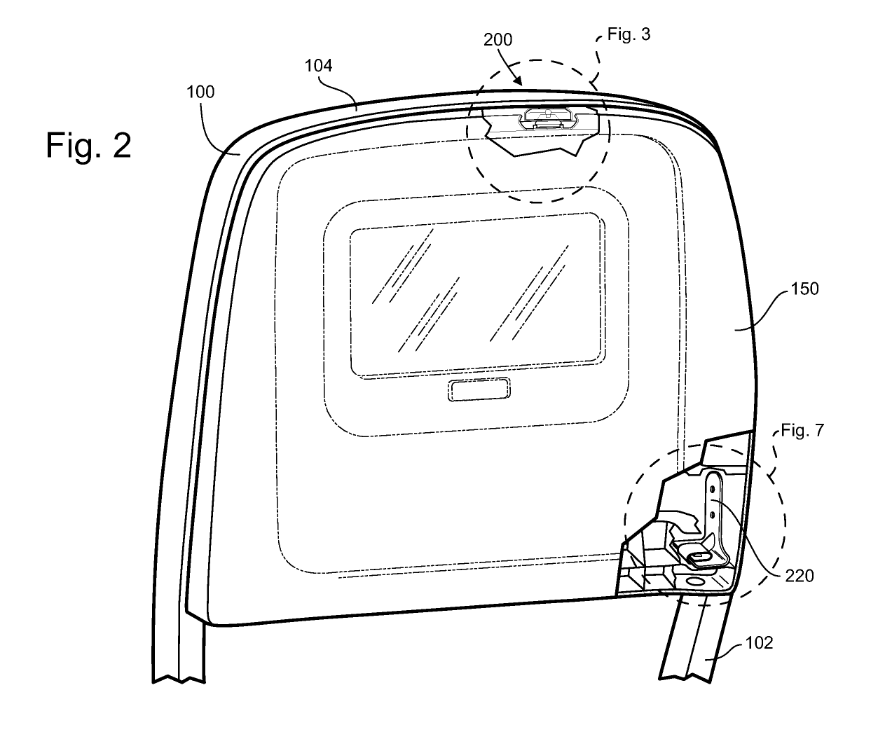

Referring to the drawings, in which identical reference numerals denote the same elements throughout the various views, FIGS. 1 and 2 illustrate a video monitor bezel 150 attached to a seat back frame 100, according to one embodiment of the present invention. The seat back frame 100 includes two generally vertical arms 102 and a generally horizontal top bar 104 that connects the upper ends of the vertical arms and defines the top of the seat back frame. The arms 102 and top bar 104 are illustrated as hollow tubular members having rectangular cross sections. They may be constructed of metals such as steel and aluminum, composite materials such as carbon fibers and resin, and suitably rigid and strong plastics. The seat back frame 100 may be a component of an airline passenger seat for example.

The bezel 150 visually fills an upper portion of the space between the vertical arms 102 and top bar 104 of the seat back frame 100, and provides a vertical platform into which the video monitor 50 is mounted as shown in FIG. 1. The video monitor 50 is sunk into a recess 152 formed in the outer surface 153 of the bezel. The seat back frame 100 is capable of assuming upright and reclined configurations, and so the degree to which the video monitor 50 is held vertical varies as it travels with the adjustable seat back frame. In the illustrated example, the bezel 150 is constructed of molded plastic. Other materials for the formation of the bezel are within the scope of these descriptions.

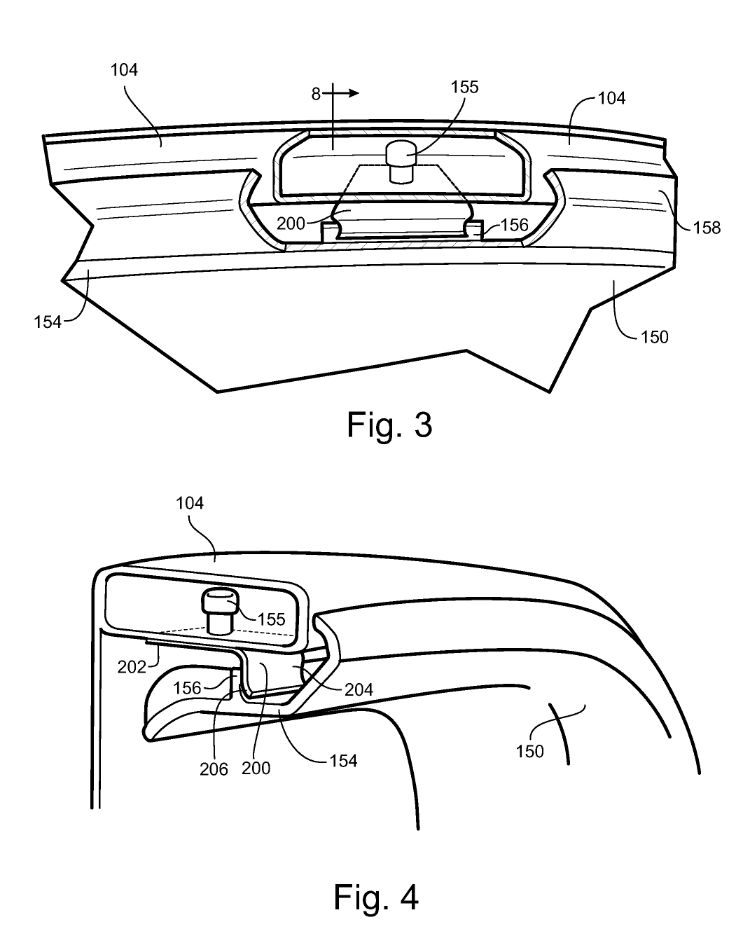

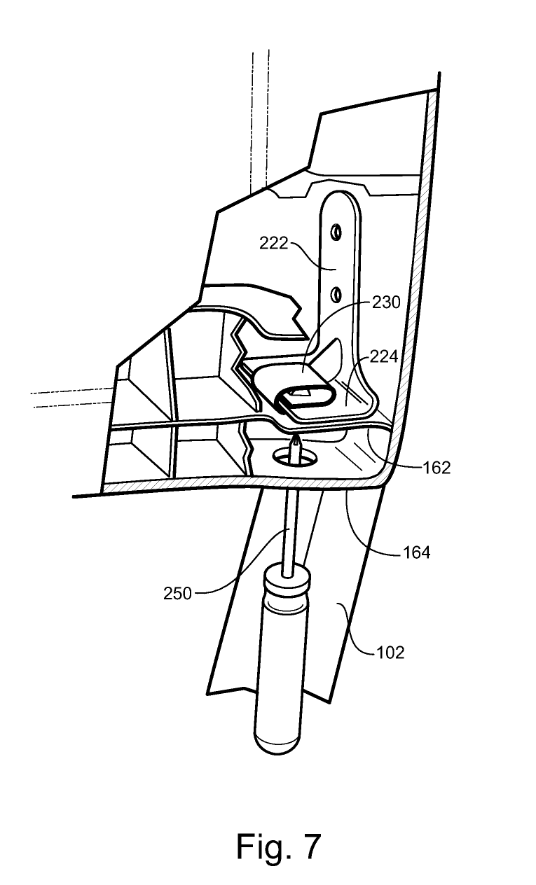

The bezel 150 is attached to the seat back frame 100 by two upper spring clips and two lower rigid brackets along the inner side of the bezel, which is opposite the outer surface and is contoured to engage the seat back frame. A right-side upper spring clip 200 and a right-side lower rigid bracket 220 are shown in broken view areas of FIG. 2 with reference to FIGS. 7 and 3 respectively. A left-side upper spring clip is present behind the bezel 150 in symmetric relation to the illustrated right-side upper spring clip 200 without being expressly shown in FIG. 2. Similarly, a left-side lower rigid bracket is present behind the bezel 150 in symmetric relation to the illustrated right-side lower rigid bracket 220 without being expressly shown in FIG. 2. The upper spring clips 200 and the lower rigid brackets 220 are connected to and carried by the seat back frame 100 as described in the following. The bezel 150 is then easily removably attached to the seat back frame by the spring clips and rigid brackets.

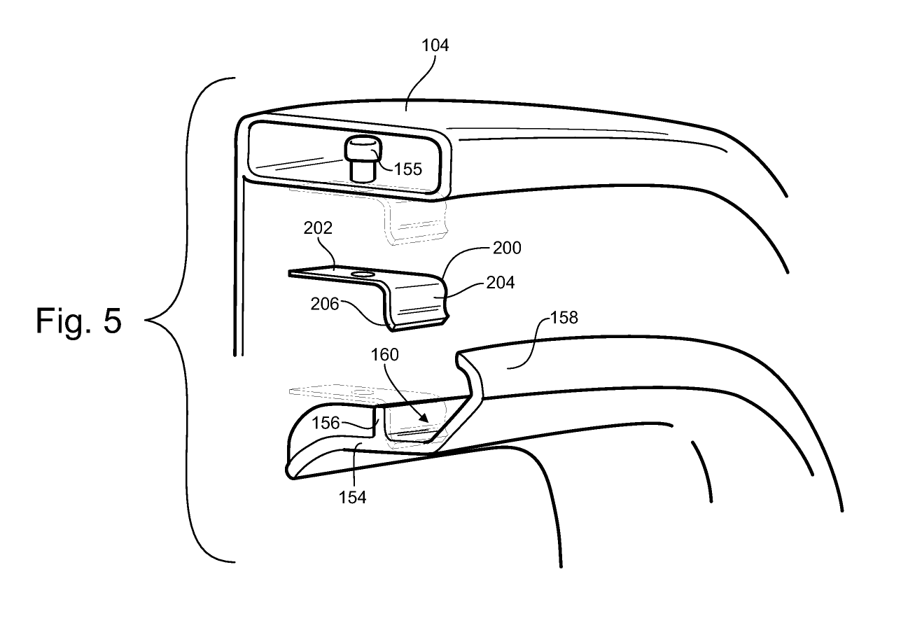

FIGS. 3 and 4 illustrate in detail the attachment of the bezel 150 to the top bar 104 of the seat back frame by the upper spring clip 200. FIG. 5 shows the components involved in the attachment in an exploded view. The spring clip 200 is formed into an L-shape from a band or sheet of resilient material such as spring steel. The spring clip 200 is connected to the top bar 104 of the seat back frame 100 by a rivet or bolt 155. The spring clip 200 has a planar mounting plate 202 connected to top bar 104, a retaining shoulder 204 formed as approximately perpendicular to the mounting plate to define the L-shape, and a turned edge 206 extending away from the mounting plate to guide a retaining lip 156 of the bezel 150 as the bezel approaches the spring clip during assembly procedures.

The bezel 150 has an outer peripheral wall 154, from which the retaining lip 156 extends outwardly, and a hooked flange 158 extending outwardly from the peripheral wall such that a channel 160 (FIG. 5) is formed between the lip 156 and flange 158. When the bezel 150 is connected to the seat frame 100, the hooked flange 158 of the bezel abuts the top bar 104 of the seat frame, and the retaining shoulder 204 of the spring clip is flexed slightly outward from the mounting plate 202 by the retaining lip 156. The spring force of the flexed retaining shoulder 204 holds the upper end of the bezel firmly in its assembled position.

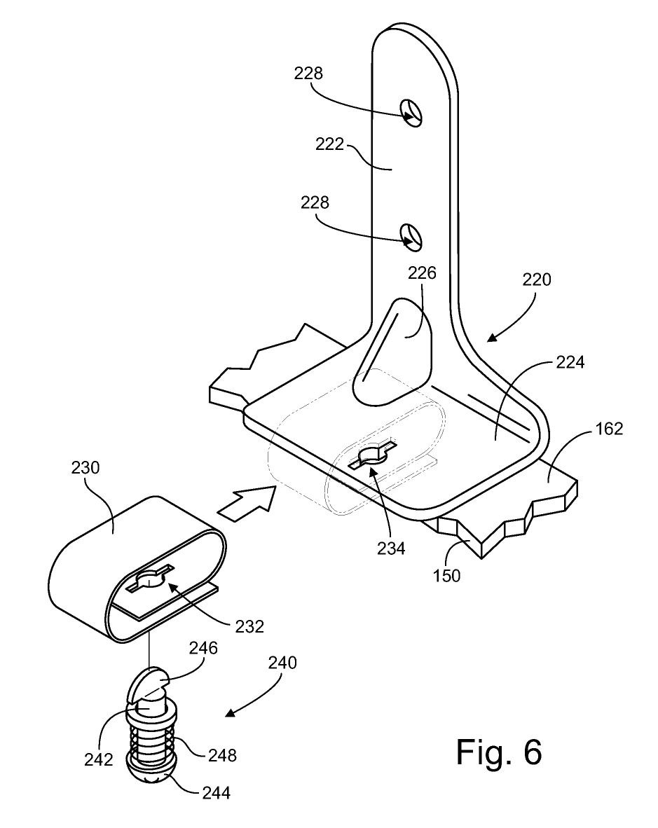

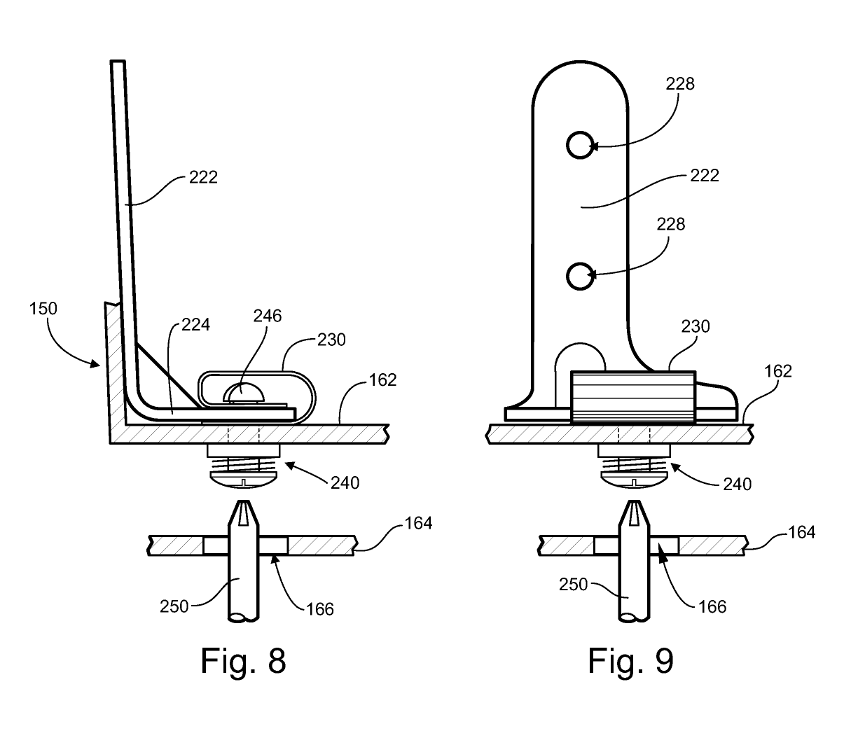

FIGS. 7-9 illustrate in detail the attachment of the bezel 150 to the L-shaped rigid bracket 220. FIG. 6 shows the components involved in the attachment in an exploded view. The rigid bracket 220 has a planar mounting plate 222, a retaining shelf 224 formed as approximately perpendicular to the mounting plate to define the L-shape, and a diagonal cross piece 226 that strengthens the perpendicular arrangement of the retaining shelf and mounting plate. The rigid bracket 220 is formed from a rigid and durable material such as aluminum or steel. The planar mounting plate 222 is connected to the vertical arm 102 of the seat back frame by bolts or rivets though holes 228 formed in the mounting plate. A rolled spring retainer 230 is first clipped onto the retaining shelf 224. Overlapping portions of the rolled spring retainer 230 have aligned apertures 232 formed as central round holes and radial slots (FIG. 6). The retaining shelf 224 has a matching aperture 234. The rolled spring retainer 230 is clipped onto the retaining shelf 224 with the apertures 232 and 234 aligned.

A spring-loaded connector 240, which engages the rolled spring retainer 230, removably attaches the bezel 150 to the retaining shelf 224. The connector 240 has a cylindrical shaft 242, a screw head 244 at one end thereof, and a wide key 246 opposite the screw head. When the bezel 150 is to be attached to the retaining shelf 224, the wide key 246 is passed through the radial slots of the aligned apertures 232 and 234 of the rolled spring retainer 230 and retaining shelf 224, with the cylindrical shaft 242 of the connector 240 passed through the central round holes of the apertures 232 and 234. The connector 240 is then turned one quarter of a rotation about the shaft 242 so that the wide key 246 loses alignment with the radial slots of the apertures 232 and 234 and is restricted by its size from passing through the central round holes of the apertures. This removably locks the attachment of the bezel 150 to the retaining shelf 224. A spring 248 coiled around the shaft 242 of the connector 240 biases the connector away from attachment, and thus presses the retaining shelf 224 and bezel 150 together when the key 246 is in its locked position.

In more detail as shown in FIGS. 7-9, a first internal rib 162 extending from a lower portion of the bezel 150 is trapped between the retaining shelf 224 and the compressed spring 248, with the shaft 242 of the connector 240 passed through an aperture formed through the first rib. A lower peripheral wall 164 of the bezel 150 is spaced from the first rib 162 and has an access hole 166 through which the screw head 244 of the connector 240 can be conveniently reached by a screwdriver 250.

Installing the bezel 150 onto the seat back frame 100 begins with tilting the bezel 150 relative to the seat back frame such that the top portion of the bezel approaches the top bar 104 and the bottom of the bezel is spaced from the seat back frame. The hooked flange 158 (FIG. 4) of the bezel is brought into contact with the top bar 104. The turned edge 206 of the spring clip 200 enters the channel 160 (FIG. 5) and guides the retaining lip 156 into abutment with the retaining shoulder 204 of the bezel as the bottom of the bezel is moved toward the seat back frame. The lower portion of the bezel then reaches its assembled position and the connector 240 is accessed by a screwdriver as shown in FIGS. 7-9. The spring loaded connector 240 is then compressed by the screwdriver to extend the keys 246 through the apertures 232 and 234 of the rolled spring retainer 230 and retaining shelf 224. The connected 240 is then turned one quarter turn to secure it in its locked position.

While specific embodiments of the present invention have been described, it will be apparent to those skilled in the art that various modifications thereto can be made without departing from the spirit and scope of the invention. Accordingly, the foregoing description of the preferred embodiment of the invention and the best mode for practicing the invention are provided for the purpose of illustration only and not for the purpose of limitation.

What is claimed is:

1. A bezel assembly for mounting a video monitor onto a back of a passenger seat, the bezel assembly comprising:
a bezel including an outer surface in which a recess is formed for receiving a video monitor, an inner side contoured to engage a seat back frame opposite the outer surface, a retaining lip extending outwardly from the inner side, and an internal rib connected to the inner side;
at least one spring clip for attaching the retaining lip to the seat back frame; and
at least one spring-loaded connector for attaching the internal rib to the seat back frame.

2. A bezel assembly according to claim 1, wherein the spring clip comprises a mounting plate, a retaining shoulder connected perpendicularly to the mounting plate, and a turned edge connected to the retaining shoulder and extending away from the mounting plate to guide the retaining lip of the bezel.

3. A bezel assembly according to claim 1, wherein the bezel has peripheral wall from which the retaining lip extends outwardly, a hooked flange extending outwardly from the peripheral wall, and a channel formed between the retaining lip and the hooked flange.

4. A bezel assembly according to claim 1, wherein the spring-loaded connector comprises a cylindrical shaft and a wide key, wherein the bezel assembly further comprises a bracket for attaching the internal rib to the seat back frame in cooperation with the spring-loaded connector, and wherein an aperture is formed through the bracket, the aperture having a central hole for receiving the shaft and radial slots for passage of the wide key.

5. A bezel assembly according to claim 4, wherein the bracket comprises a mounting plate and a retaining shelf in which the aperture is formed, and wherein the retaining shelf is connected perpendicularly to the mounting plate.

6. A bezel assembly according to claim 1, wherein the bezel has a peripheral wall in which an access hole is formed for permitting access to the spring-loaded connector.

7. A method of attaching a video monitor bezel onto a back of a passenger seat, the method comprising:
providing a seat back frame;
providing a bezel having an outer surface in which a recess is formed for receiving a video monitor, an inner side contoured to engage the seat back frame opposite the outer surface, a retaining lip extending outwardly from the inner side, and an internal rib connected to the inner side;
providing a spring clip connected to the seat back frame; and
providing a connector having a cylindrical shaft and a wide key;
attaching the retaining lip to the seat back frame by engaging the retaining lip with the spring clip; and
attaching the internal rib to the seat back frame by a quarter turn of the connector.
